(19) United States
(12) Patent Application Publication
(10) Pub. No.: US 2006/0270246 A1
(43) Pub. Date: Nov. 30, 2006

(54) Method of manufacturing a semiconductor device

(76) Inventor: Hajime Nagano, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/414,359

(22) Filed: May 1, 2006

(30) Foreign Application Priority Data
May 31, 2005 (JP) 2005-159418

(51) Int. Cl. H01L 21/31

(52) U.S. Cl. 438/773

(57) ABSTRACT

A method of manufacturing a semiconductor device, includes preparing a film formation system including a film formation furnace and a heater heating a work piece placed in the furnace via a furnace wall of the furnace, acquiring a correlation between a first information value relevant to a thickness of a deposition film deposited using the film formation system and a second information value based on an adhesion film adhered to the furnace wall with respect to each kind of deposition film, adjusting a deposition condition of a deposition film to be deposited on a work piece based on the correlation, and depositing a deposition film on a work piece under the adjusted deposition condition.

### CROSS-REFERENCE TO RELATED APPLICATIONS

This application is based upon and claims the benefit of priority from prior Japanese Patent Application No. 2005-159418, filed May 31, 2005, the entire contents of which are incorporated herein by reference.

### BACKGROUND OF THE INVENTION

1. Field of the Invention

The present invention relates to a method of manufacturing a semiconductor device.

2. Description of the Related Art

When film formation is carried out on a semiconductor substrate, a furnace wall of a film formation (deposition) furnace is formed with a film in addition to the semiconductor substrate. If the furnace wall is not cleaned for each film formation, the thickness of film deposited on the furnace wall increases every when the film formation is carried out. For this reason, if heating is carried out using a heater arranged outside the furnace, heat efficiency is worsened because the thickness of film deposited on the furnace wall gradually increases. As a result, the film thickness deviates from a target film thickness.

If only one kind of film is formed using one furnace, the thickness of a test piece is obtained from a certain film formation, and thereafter, the measured result is reflected onto the next film formation. By doing so, it is possible to achieve proper thickness control. However, if several kinds of films are formed using one furnace, the deposition condition is different depending on the kind of films. For this reason, the foregoing thickness control is not applied to this case.

JPN. PAT. APPLN. KOKAI Publication No. 2003-249491 has proposed a film formation method of reducing thickness variations as the well-known technique. However, the foregoing proposal has not been made on the assumption that several kinds of films are formed using one furnace. Moreover, the proposal has not been made for the purpose of solving a problem resulting from a film adhered (deposited) to the furnace wall.

Conventionally, it is difficult to achieve proper thickness control if several kinds of films are formed using one furnace. As a result, it is difficult to manufacture a excellent semiconductor device having a proper thickness.

### BRIEF SUMMARY OF THE INVENTION

According to an aspect of the present invention, there is provided a method of manufacturing a semiconductor device, comprising: preparing a film formation system including a film formation furnace and a heater heating a work piece placed in the furnace via a furnace wall of the furnace; acquiring a correlation between a first information value relevant to a thickness of a deposition film deposited using the film formation system and a second information value based on an adhesion film adhered to the furnace wall with respect to each kind of deposition film; adjusting a deposition condition of a deposition film to be deposited on a work piece based on the correlation; and depositing a deposition film on a work piece under the adjusted deposition condition.

### BRIEF DESCRIPTION OF THE SEVERAL VIEWS OF THE DRAWING

FIG. 1 is a schematic view showing the structure of a film formation system according to first to fourth embodiments of the present invention;

FIG. 2 is a flowchart to explain the film formation method according to first to fourth embodiments of the present invention;

FIG. 3 is a table to explain the method of acquiring correlation according to the first embodiment of the present invention;

FIG. 4A to FIG. 4D are views showing one example of the correlation according to the first embodiment of the present invention;

FIG. 5 is a view to explain the method of acquiring correlation according to the second embodiment of the present invention;

FIG. 6A to FIG. 6D are views showing one example of the correlation according to the second embodiment of the present invention;

FIG. 7 is a view to explain the method of acquiring correlation according to the third embodiment of the present invention;

FIG. 8A to FIG. 8D are views showing one example of the correlation according to the third embodiment of the present invention;

FIG. 9 is a view to explain the method of acquiring correlation according to the fourth embodiment of the present invention; and

FIG. 10A to FIG. 10D are views showing one example of the correlation according to the fourth embodiment of the present invention.

### DETAILED DESCRIPTION OF THE INVENTION

Embodiments of the present invention will be described below with reference to the accompanying drawings.

### First Embodiment

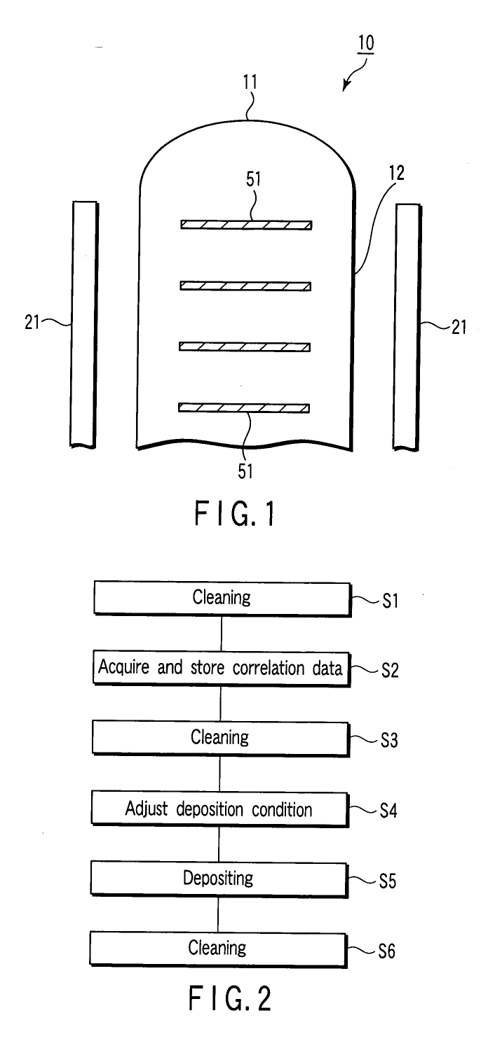

FIG. 1 is a schematic view showing the structure of a film formation system (e.g., used for CVD (chemical vapor deposition) according to the first embodiment. In the following second to fourth embodiments, the film formation system shown in FIG. 1 is used.

A film formation system 10 shown in FIG. 1 is a batch type film formation system. Several semiconductor wafers (semiconductor substrates) 51 are arranged as work pieces in a film formation furnace 11. Heaters 21 are arranged around a furnace wall 12 of the film formation furnace 12. The furnace wall 12 is transparent; therefore, radiant heat (radiant light) from the heaters 21 is supplied to the wafers 51 through the furnace wall 12 so that the wafers 51 are heated. The film formation furnace 11 is supplied with source gas for film formation from a gas supplier (not shown). A desired film is deposited on the wafer 51 in a state of being heated by the heater 21.

In the film formation system shown in FIG. 1, when a film is deposited on the wafer 51, a film is also deposited on the furnace wall 12. If the furnace wall 12 is not cleaned for each film formation, the thickness of the film deposited on (adhered to) the furnace wall 12 increases every when the film formation is carried out. For this reason, the thickness of the film deposited on the furnace wall 12 gradually increases, and thereby, heat efficiency by the heater 21 with respect to the wafer 51 is worsened. As a result, the following problem arises; specifically, the thickness of the film deposited on the wafer 51 deviates from a desired thickness (target thickness). Thus, if several kinds of films are formed using one furnace 11, the film formation (deposition) condition is different depending on the kind of films; for this reason, proper thickness control is not carried out.

According to the embodiment, the following film formation is employed so that a desired thickness is obtained.

FIG. 2 is a flowchart to schematically explain the film formation method according to the embodiment. In the following second to fourth embodiments, the basic flow is the same as shown in the flowchart of FIG. 2.

The furnace wall 12 is cleaned (S1), and thereafter, a correlation between first and second information values given below is acquired for each kind of deposition film (S2). The first information value relates to the thickness of a deposition film deposited using the film formation system 10. The second information value is based on an adhesion film adhered to the furnace wall 12. In the embodiment, the second information value includes information on the thickness of the adhesion film adhered (deposited) to the furnace wall 12. Specifically, the correlation is acquired in the following manner.

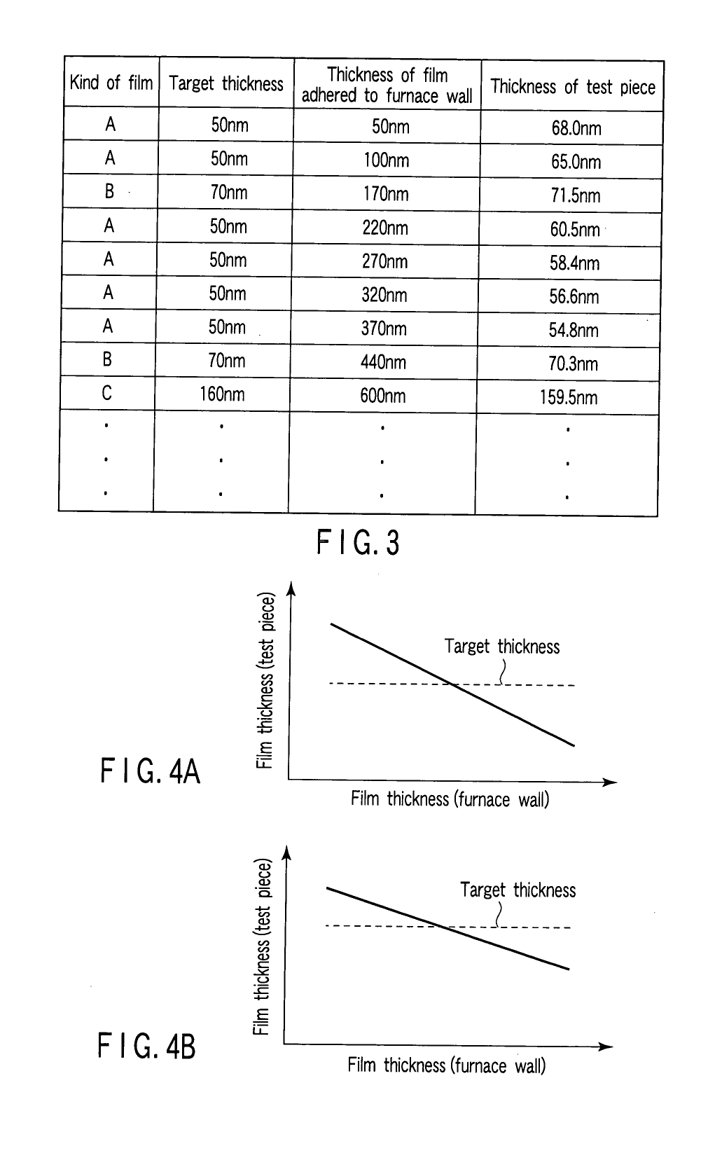

A wafer as a test piece is placed in the furnace 11, and, the relationship between the thicknesses given below is obtained. One is a thickness of a deposition film deposited on each test piece in each film formation. Another is a thickness of an adhesion film adhered to the furnace wall 12 (i.e., total thickness after the furnace wall 12 is cleaned). FIG. 3 is a table showing one example of the relationship.

In FIG. 3, three kinds of films A, B and C (A, B and C represent the kind of films) are deposited according to their film formation recipes until the next cleaning is started after cleaning is completed. Target thicknesses of the films A to C are 50 nm, 70 nm and 160 nm, respectively. The thickness of the deposition film on each test piece is measured using a thickness measuring instrument. The total thickness of the adhesion film adhered to the furnace wall 12 (i.e., total thickness of films A to C) is given by adding the target thickness of these films. For example, according to the case of the film A, the thickness of the adhesion film on the furnace wall 12 gradually increases while the thickness of the deposition film on the test piece decreases. This results from the following reason. Specifically, transmittance (transmissivity) of radiant light (radiant heat) from the heater 21 decreases as the thickness of the film deposited on the furnace wall 12 increases. As a result, the heating temperature by the heater 21 with respect to the wafer 51 decreases.

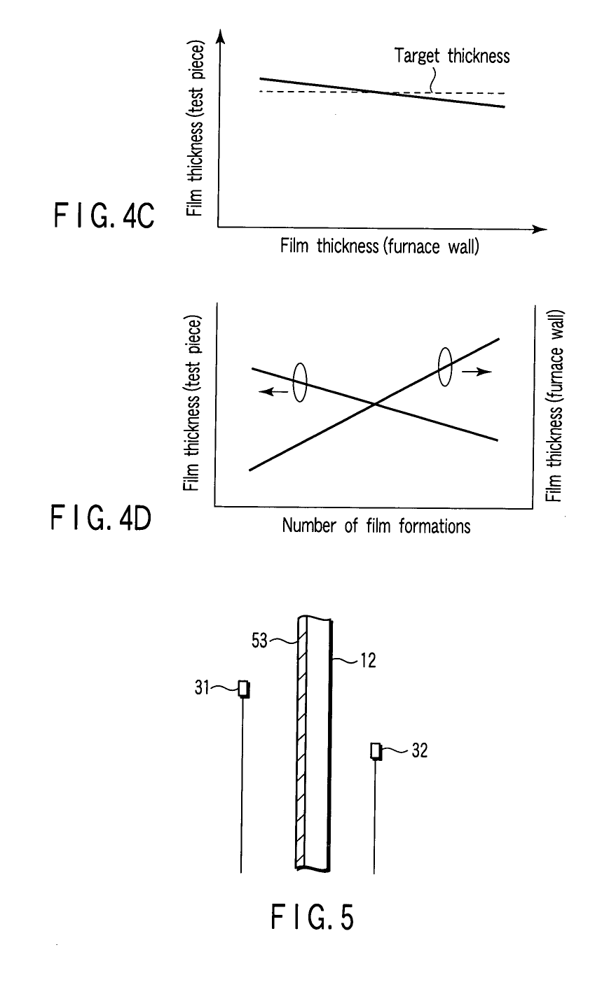

Based on the measured result thus obtained, a correlation between thickness of test piece and thickness of the adhesion film on the furnace wall (total thickness of films A to C) is given with respect to individual films A to C. FIG. 4A is a view showing a correlation relevant to the film A, FIG. 4B is a view showing a correlation relevant to the film B, and FIG. 4C is a view showing a correlation relevant to the film C. As seen from the foregoing description, the thickness of an adhesion film 53 adhered to the furnace wall 12 increases, and thereby, the internal temperature of the furnace goes downs; as a result, a deposition (film formation) rate reduces. In other words, as shown in FIG. 4D, the number of film formation (deposition) times increases, and thereby, the thickness of the adhesion film on the furnace wall increases while the film thickness on the wafer (test piece) decreases. As a result, correlations shown in FIG. 4A to FIG. 4C are obtained. In films B and C, the reduction ratio of the thickness of the test piece is smaller as compared with the film A. This is because films B and C have smaller deposition temperature dependency of the deposition rate as compared with the film A. The correlation data thus obtained is stored in a storage section of a controller (not shown).

The correlation data with respect to each of films A to C is acquired in the manner described above, and thereafter, the furnace wall 12 is cleaned to remove the film adhered to the furnace wall 12 (S3). Thereafter, film A, B or C is deposited on the wafer as the test piece using the acquired correlation data. Specifically, based on the acquired correlation, a deposition condition of the deposition film (film A, B or C) deposited on the wafer 51 is adjusted for each film formation (S4). A film is deposited on the wafer 51 according to the deposition condition thus adjusted (S5). When adjusting the deposition condition of the deposition film, deposition time is adjusted, and deposition conditions other than the deposition time are predetermined, and then, maintained. Specifically, film A, B or C is deposited according to the same film formation recipe as the film formation recipe used for the test piece. The film formation will be explained below giving one example.

For example, if the film formation of the film B is carried out, a film having the total thickness of 300 nm is deposited on the furnace wall 12 by film formation so far. Before the film formation of the film B is started, the thickness on the test piece when thickness of the film deposited on the furnace wall 12 is 300 nm is read from the correlation relevant to the film B shown in FIG. 4B. In this case, if the thickness of the test piece is 72 nm and deposition time is 36 minutes, the deposition rate of the film B is 2 nm/minute. Therefore, if the target thickness of the film B is 70 nm, the deposition time is adjusted to 35 minutes, thereby obtaining a desired target thickness (70 nm). In other words, the deposition rate is assumed as constant in one-time film formation. Using the deposition rate when starting the film formation obtained from the foregoing correlation, the deposition time is adjusted to obtain a desired target thickness.

In the manner described above, film A, B or C is deposited using deposition time adjusted based on the correlation data for each film formation. Then, the furnace wall 12 is cleaned when the thickness of the film deposited on the furnace wall reaches a predetermined value (S6).

According to the embodiment, correlation data is previously acquired for each kind of the deposition film. Then, based on the acquired correlation data, the deposition condition of the deposition film to be deposited on the wafer (work piece) is adjusted. Therefore, if several kinds of films (films A, B and C) are formed using the identical furnace 11, a film (film A, B or C) is deposited on the wafer having an adjusted proper thickness. As a result, it is possible to manufacture a semiconductor device having a properly controlled thickness and high performance.

Moreover, according to the embodiment, the thickness of the adhesion film adhered to the furnace wall 12 is used as an information value (parameter) based on the adhesion film adhered to the furnace wall 12. The thickness of the adhesion film is readily acquired as the total value of the target thickness. Therefore, it is extremely easy to acquire the parameter.

In the foregoing embodiment, the thickness data (correlation data) of the deposition film on the test piece may be acquired via a dedicated process. In this case, the thickness data may be acquired in a process of forming a deposition film on the work piece. In other words, the test piece may be placed in the furnace 11 when forming the deposition film on the work piece. By doing so, the following two processes are concurrently carried out in a serial process until the next cleaning after the preceding cleaning. One is a process of forming the deposition film on the test piece. Another is a process of acquiring the thickness of the deposition film on the test piece. Using the thickness data of the deposition film on the test piece thus acquired, the correlation data stored in the storage section of the controller may be updated.

According to the foregoing embodiment, the film thickness on the test piece is used as the first information value for specifying the correlation. For example, a value relevant to the thickness of the deposition film such as deposition rate may be used as the first information value. Moreover, according to the foregoing embodiment, the thickness of the adhesion film adhered to the furnace wall 12 is used as the second information value for specifying the correlation. In this case, any other forms may be used as the second information value so long as they relate to the thickness of the adhesion film.

In the embodiment, the batch type film formation system is used as the film formation system 10. In this case, even if a single wafer type film formation system is used, the foregoing method is applicable.

### Second Embodiment

The second embodiment of the present invention will be described below. The structure of the film formation system and the procedure step are basically the same as the first embodiment. Therefore, the matters described in the first embodiment are applicable to this embodiment so long as no special reference is made. The matter different from the first embodiment will be mainly explained below.

In the first embodiment, the thickness of the adhesion film adhered to the furnace wall 12 is used as the second information value for specifying correlation. In the second embodiment, the difference between internal and external temperatures of the furnace 11 is used as the second information value.

If the thickness of the adhesion film adhered to the furnace wall 12 is used as the second information value, the following conditions should be considered. Specifically, it is general that each transmittance of films A to C is mutually different in some degree. Moreover, films A to C having different transmittance adhere to the furnace wall 12 in a state of being mixed. Thus, the transmittance of the adhesion film is not necessarily constant even if the thickness of the adhesion film adhered to the furnace wall 12 is the same. In other words, even if the total thickness of the adhesion films is the same, some difference occurs in the heating temperature of the wafer 51. Therefore, if the thickness of the adhesion film adhered to the furnace wall 12 is used as the second information value like the first embodiment, the second information value is readily acquired. However, there is a possibility that some errors occurs in the thickness of the film deposited on the wafer. According to the second embodiment, the following method is employed to reduce a thickness error of the film deposited on the wafer.

According to the second embodiment, temperature detecting elements 31 and 32 are arranged inside and outside the furnace 11, respectively, as shown in FIG. 5. In FIG. 5, a reference numeral 53 denotes an adhesion film adhered to the furnace wall 12. A thermocouple is used as the foregoing temperature detecting elements 31 and 32.

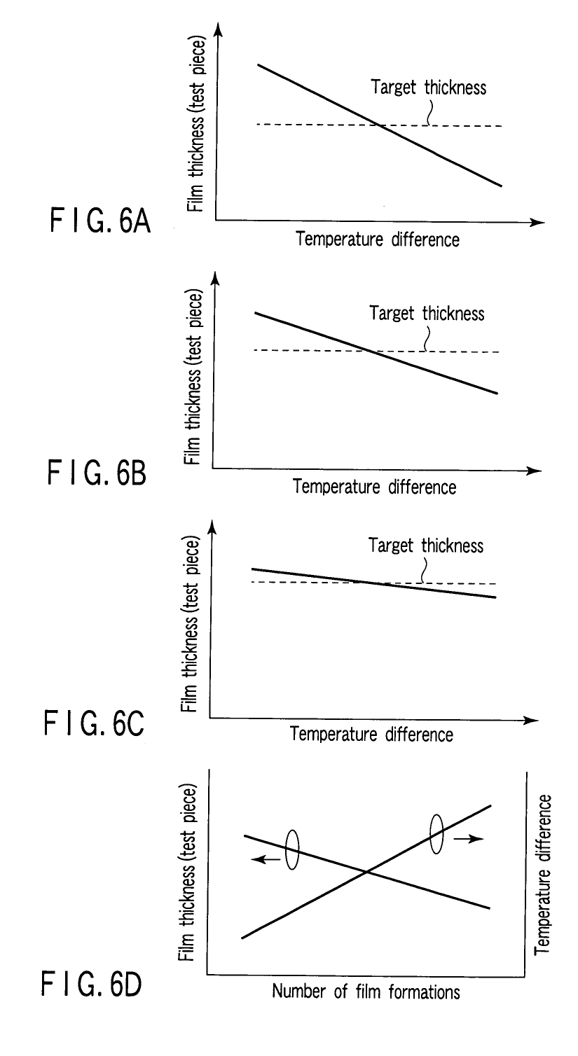

In step S2 of FIG. 2, the difference between temperatures detected by temperature detecting elements 31 and 32 is acquired as the second information value when acquiring correlation between first and second information values. FIG. 6A is a view showing a correlation relevant to the film A, FIG. 6B is a view showing a correlation relevant to the film B, and FIG. 6C is a view showing a correlation relevant to the film C. The thickness of the adhesion film 53 adhered to the furnace wall 12 increases, and thereby, the internal temperature of the furnace goes downs; as a result, a deposition (film formation) rate reduces. In other words, as shown in FIG. 6D, the number of film formation (deposition) times increases, and thereby, the difference between temperatures inside and outside the furnace increases while the film thickness on the wafer (test piece) decreases. As a result, correlations shown in FIG. 6A to FIG. 6C are obtained.

Based on the correlation thus obtained, the deposition condition of the deposition film (film A, B or C) to be deposited on the wafer 51 is adjusted for each film formation in the same manner as the first embodiment (S4). Specifically, the difference between temperatures detected by the temperature detecting elements 31 and 32 is measured in the film formation. Referring to the correlation data of FIG. 6A, FIG. 6B or FIG. 6C, deposition time is adjusted in accordance with the measured temperature difference. In also, case, like the first embodiment, the deposition rate is assumed as constant in one-time film formation. Using the deposition rate when starting the film formation obtained from the foregoing correlation, the deposition time is adjusted to obtain a desired target thickness. Then, a film is deposited on the wafer 51 according to the adjusted deposition time (S5).

In the second embodiment, correlation data is previously acquired for each kinds of the deposition film like the first embodiment. Based on the correlation data, the deposition condition of the deposition film deposited on the wafer (work piece) is adjusted. Therefore, it is possible to manufacture a high-performance semiconductor device having a properly controlled thickness.

According to the second embodiment, the difference between internal and external temperatures of the furnace 11 is used as the second information value for specifying the correlation. Therefore, even if transmittance is different depending on the kind of film, the wafer is heated at a proper temperature; as a result, precise thickness control is carried out.

In the second embodiment, the difference between internal and external temperatures of the furnace 11 is used as the second information value for specifying the correlation. In this case, any other forms may be used as the second information value so long as they relates to the difference between temperatures.

### Third Embodiment

The third embodiment of the present invention will be described below. The structure of the film formation system and the procedure step are basically the same as the first embodiment. Therefore, the matters described in the first embodiment are applicable to this embodiment so long as no special reference is made. The matter different from the first embodiment will be mainly explained below.

In the third embodiment, the transmittance (transmissivity) of the furnace wall to which the adhesion film adheres is used as the second information value for specifying correlation. The explanation will be made below.

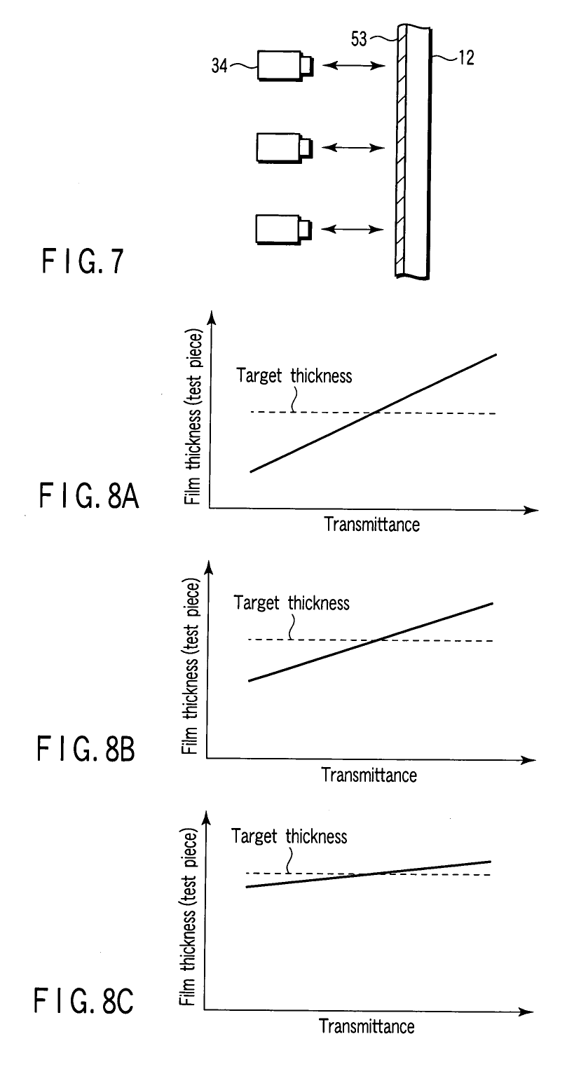

According to the third embodiment, an infrared radiation and detection device 34 is arranged inside the furnace 11 as depicted in FIG. 7.

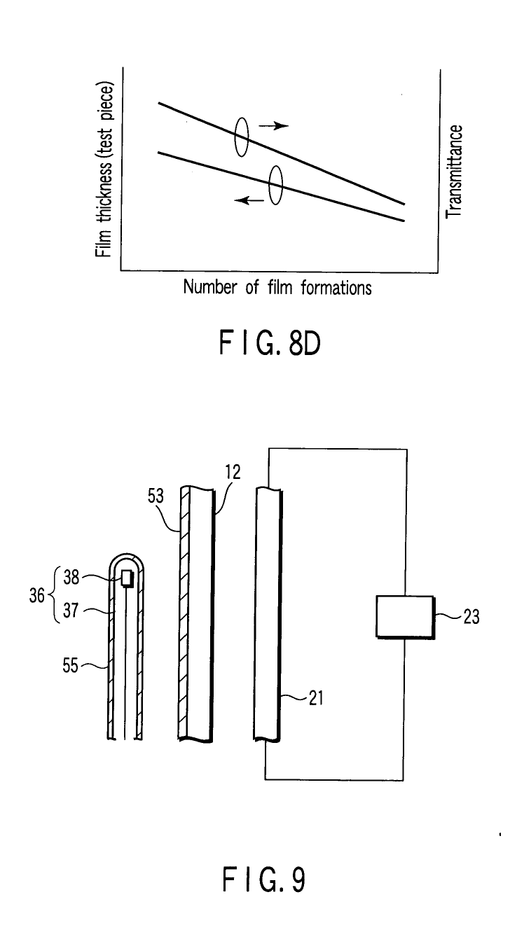

In step S2 of FIG. 2, when acquiring a correlation between first and second information values, infrared radiation and detection are carried out with respect to the furnace wall 12 using the infrared radiation and detection device 34 in the third embodiment. Infrared transmittance obtained from the detection result is used as the second information value. FIG. 8A is a view showing a correlation relevant to the film A, FIG. 8B is a view showing a correlation relevant to the film B, and FIG. 8C is a view showing a correlation relevant to the film C. The thickness of the adhesion film 53 adhered to the furnace wall 12 increases, and thereby, the infrared transmittance decreases; as a result, a deposition (film formation) rate reduces. In other words, as shown in FIG. 8D, the number of film formation (deposition) times increases, and thereby, the infrared transmittance decreases while the film thickness on the wafer (test piece) decreases. As a result, correlations shown in FIG. 8A to FIG. 8C are obtained.

Based on the correlation thus obtained, the deposition condition of the deposition film (film A, B or C) deposited on the wafer 51 is adjusted for each film formation in the same manner as the first embodiment (S4). Specifically, the infrared transmittance is measured based on infrared rays detected by the infrared radiation and detection device 34 in the film formation. Referring to the correlation data of FIG. 8A, FIG. 8B or FIG. 8C, deposition time is adjusted in accordance with the measured infrared transmittance. In also, case, like the first embodiment, the deposition rate is assumed as constant in one-time film formation. Using the deposition rate when starting the film formation obtained from the foregoing correlation, the deposition time is adjusted to obtain a desired target thickness. Then, a film is deposited on the wafer 51 according to the adjusted deposition time (S5).

In the third embodiment, correlation data is previously acquired for each kinds of the deposition film like the first embodiment. Based on the correlation data, the deposition condition of the deposition film deposited on the wafer (work piece) is adjusted. Therefore, it is possible to manufacture a high-performance semiconductor device having-a properly controlled thickness.

According to the third embodiment, the transmittance of the furnace wall to which the adhesion film adheres is used as the second information value for specifying the correlation. Therefore, even if the transmittance is different depending on the kind of film, the wafer is heated at a proper temperature; as a result, precise thickness control is carried out like the second embodiment.

In the third embodiment, the transmittance of the furnace wall to which the adhesion film adheres is used as the second information value. In this case, any other forms may be used as the second information value so long as they relates to the transmittance.

### Fourth Embodiment

The fourth embodiment of the present invention will be described below. The structure of the film formation system and the procedure step are basically the same as the first embodiment. Therefore, the matters described in the first embodiment are applicable to this embodiment so long as no special reference is made. The matter different from the first embodiment will be mainly explained below.

In the fourth embodiment, power of heater for heating a wafer is used as the second information value for specifying correlation. The explanation will be made below.

In the fourth embodiment, a temperature detecting element (thermocouple) 36 is arranged inside the furnace 11 to detect a temperature of a wafer placed in the furnace 11, as illustrated in FIG. 9. The temperature detecting element 36 has a transparent wall portion 37 formed of a quartz tube, and a sensor portion 38 arranged in the wall portion 37. A heater 21 is connected with a power controller 23, which controls the power of the heater 21 so that the temperature of the sensor portion 38 becomes constant.

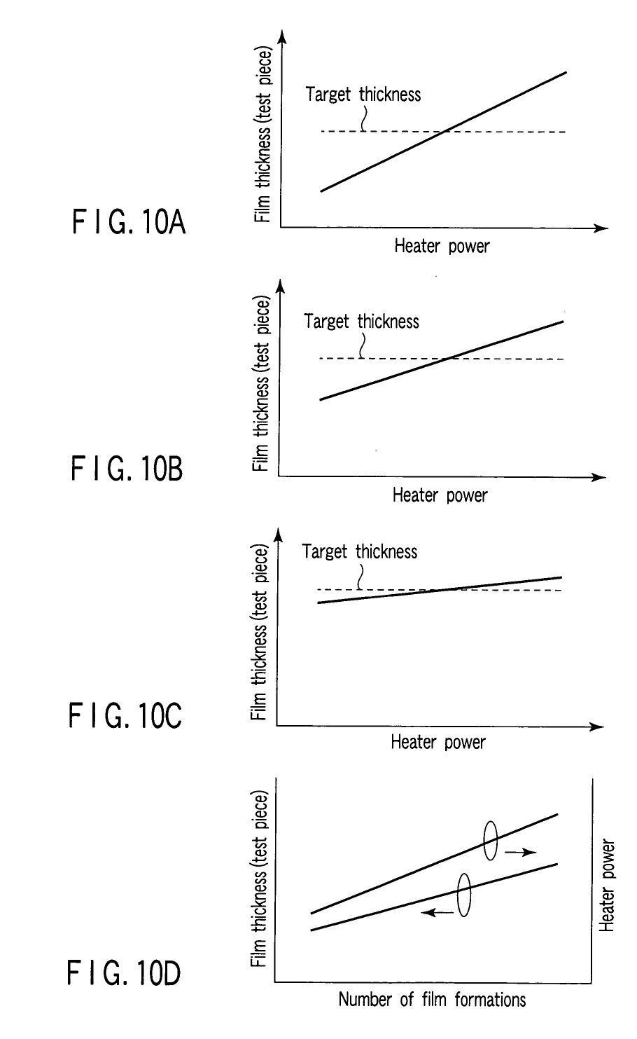

In step S2 of FIG. 2, when acquiring a correlation between first and second information values, the power of the heater 21 controlled by the power controller 23 is acquired as the second information value in the fourth embodiment. FIG. 10A is a view showing a correlation relevant to the film A, FIG. 10B is a view showing a correlation relevant to the film B, and FIG. 10C is a view showing a correlation relevant to the film C.

The power of the heater 21 is controlled so that the temperature of the sensor portion 38 of the temperature detecting element 36 becomes constant. The thickness of the adhesion film 53 adhered to the furnace wall 12 increases, and thereby, radiant heat from the heater 21 is hard to reach the wafer; for this reason, the power of the heater 21 increases. If the temperature of the sensor portion 38 fully coincides with the temperature of the wafer placed in the furnace 11, the thickness of the deposition film on the wafer (test piece) is constant even if the heater power increases. However, if the thickness of the adhesion film 53 on the furnace wall 12 increases, the thickness of an adhesion film 55 on the wall portion 37 of the temperature detecting element 36 inevitably increases. For this reason, in fact, the temperature of the sensor portion 38 of the temperature detecting element 36 becomes lower than the wafer temperature. Therefore, if the thickness of an adhesion film 55 on the wall portion 37 increases (i.e., the thickness of the adhesion film 53 adhered to the furnace wall 12 increases), the heater 21 is excessively heated, and the temperature of the wafer heated by the heater 21 increases in fact. As a result, the thickness of the deposition film on the wafer also increases. In other words, as shown in FIG. 10D, the number of film formation (deposition) times increases, and thereby, the heater power increases, and the film thickness on the wafer (test piece) increases. From the foregoing reasons, correlations shown in FIG. 10A to FIG. 10C are obtained.

Based on the correlation thus obtained, the deposition condition of the deposition film (film A, B or C) deposited on the wafer 51 is adjusted for each film formation in the same manner as the first embodiment (S4). Specifically, the power of the heater 21 controlled by the power controller 23 is measured in the film formation. Referring to the correlation data of FIG. 10A, FIG. 10B or FIG. 10C, deposition time is adjusted in accordance with the heater power. In also, case, like the first embodiment, the deposition rate is assumed as constant in one-time film formation. Using the deposition rate when starting the film formation obtained from the foregoing correlation, the deposition time is adjusted to obtain a desired target thickness. Then, a film is deposited on the wafer 51 according to the adjusted deposition time (S5).

In the fourth embodiment, correlation data is previously acquired for each kinds of the deposition film like the first embodiment. Based on the correlation data, the deposition condition of the deposition film deposited on the wafer (work piece) is adjusted. Therefore, it is possible to manufacture a high-performance semiconductor device having a properly controlled thickness.

According to the fourth embodiment, the heater power is used as the second information value for specifying the correlation, and thus, the foregoing control is carried out. Therefore, even if the temperature of the temperature detecting element is different from that of the wafer, the wafer is heated at a proper temperature; as a result, precise thickness control is carried out.

In the fourth embodiment, the heater power is used as the second information value for specifying the correlation. In this case, any other forms may be used as the second information value so long as they relates to the heater power.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a semiconductor device, comprising:
preparing a film formation system including a film formation furnace and a heater heating a work piece placed in the furnace via a furnace wall of the furnace;
acquiring a correlation between a first information value relevant to a thickness of a deposition film deposited using the film formation system and a second information value based on an adhesion film adhered to the furnace wall with respect to each kind of deposition film;
adjusting a deposition condition of a deposition film to be deposited on a work piece based on the correlation; and
depositing a deposition film on a work piece under the adjusted deposition condition.

2. The method according to claim 1, wherein the deposition condition of the deposition film includes deposition time.

3. The method according to claim 1, wherein deposition conditions other than a deposition time of the deposition film is maintained in adjusting the deposition condition of the deposition film.

4. The method according to claim 1, wherein the second information value includes information value relevant to a thickness of the adhesion film.

5. The method according to claim 1, wherein the second information value includes information value relevant to a difference between internal and external temperatures of the furnace.

6. The method according to claim 1, wherein the second information value includes information value relevant to a transmittance of the furnace wall to which the adhesion film adheres.

7. The method according to claim 1, wherein the second information value includes information value relevant to a power of the heater.

8. The method according to claim 7, wherein the furnace is provided with a temperature detecting element which has a wall portion and a sensor portion arranged in the wall portion, and the power of the heater is controlled so that a temperature of the sensor portion becomes constant.

9. The method according to claim 1, wherein the first information value decreases if the second information value increases.

10. The method according to claim 1, wherein the first information value increases if the second information value increases.

11. The method according to claim 1, wherein the second information value gives an influence to a temperature of the work piece heated by the heater.

12. The method according to claim 1, wherein the adhesion film includes a plurality kinds of films.

13. The method according to claim 1, wherein the work piece includes a semiconductor substrate.

14. The method according to claim 1, further comprising: storing information relevant to the correlation.

15. The method according to claim 14, wherein depositing the deposition film on the work piece includes depositing a deposition film on a test piece.

16. The method according to claim 15, further comprising: updating the stored information relevant to the correlation based on a thickness of the deposition film deposited on the test piece.
